(19) United States
(12) Patent Application Publication
(10) Pub. No.: US 2013/0148678 A1
(43) Pub. Date: Jun. 13, 2013

(54) QUANTUM CASCADE LASER SOURCE WITH ULTRABROADBAND SPECTRAL COVERAGE

(71) Applicants: Laurent Diehl, Cambridge, MA (US); Christian Pfluegl, Cambridge, MA (US); Romain Blanchard, Cambridge, MA (US); Federico Capasso, Cambridge, MA (US)

(72) Inventors: Laurent Diehl, Cambridge, MA (US); Christian Pfluegl, Cambridge, MA (US); Romain Blanchard, Cambridge, MA (US); Federico Capasso, Cambridge, MA (US)

(73) Assignee: President and Fellows of Harvard College, Cambridge, MA (US)

(21) Appl. No.: 13/639,533

(22) PCT Filed: Mar. 28, 2011
(86) PCT No.: PCT/US11/30164

§ 371 Date: Dec. 17, 2012

Related U.S. Application Data
(60) Provisional application No. 61/320,820, filed on Apr. 5, 2010.

(51) Int. Cl. H01S 5/34; H01L 33/04; H01S 5/024

(52) U.S. Cl. CPC H01S 5/34; H01S 5/024; H01L 33/04
USPC 372/34; 372/45.01; 438/22

(57) ABSTRACT

A broadband quantum cascade laser includes multiple gain regions and a spacer layer disposed between at least two of the gain regions. The arrangement and characteristics of the gain regions and the spacer layer may be configured to reduce cross absorption between the gain regions. For example, one gain region may be configured to produce gain in an energy range in which another gain region produces absorptive effects. The thickness of the spacer layer may be selected to separate optical modes produced by adjacent gain regions while still producing a single broadband output from the quantum cascade laser. Gain competition between gain stages within a gain region may be mitigated by dividing gain stages with overlapping gain curves among multiple gain regions.

### RELATED APPLICATIONS

This application claims priority to U.S. Provisional Application No. 61/320,820, filed Apr. 5, 2010, entitled Quantum Cascade Laser Source With Ultrabroadband Spectral Coverage which is incorporated herein in its entirety.

### BACKGROUND

Quantum Cascade Lasers (QCLs) are unipolar semiconductor lasers that utilize optical transitions between confined electronic sub-bands (e.g., conduction or valence bands) of semiconductor heterostructures. As a result, the emitted photon energy is determined by the thicknesses of the wells and barriers and can be tailored by bandgap engineering. Reliable operation of QCLs in the 3-24 μm wavelength range has been achieved, which covers the so-called molecular fingerprint region of the optical spectrum. In this wavelength range, molecules have unique and strong rotational-vibrational absorption features that allow for their identification.

In a QCL, the gain medium comprises a repetition of stages connected in series, which includes, in general, two groups of quantum wells called the active region, where the laser transition takes place, and the injector region, which allows for the transport of electrons from one active region to the next. For applications that do not require broadband coverage, all of the stages in the QCL may be based on an identical active region design to maximize the gain in a narrow wavelength of interest. In contrast, QCLs with a broad gain curve, also called QCLs based on heterogeneous cascades, include a number of stages based on different active region designs with each stage having the laser transition centered at a different wavelength. In such heterogeneous stage designs, the number of stages emitting at each specific wavelength, as well as the doping level in each injector region, may be adjusted to obtain an essentially flat modal net gain across a wavelength region of interest.

FIG. 1 illustrates a schematic cross-section of two conventional ridge lasers. FIG. 1a shows a QCL optimized for high performance over a narrow wavelength range. The

waveguide core 10 consists of a single type of gain stage that supports a single mode TM00. Waveguide core 10 is grown between an upper cladding layer 12 and a lower cladding layer 14 disposed on a substrate 16. One or more contact layers 18 are formed in contact with upper cladding layer 12 and lower cladding layer 14 for connecting one or more contacts 20. One or more contacts 20 may be connected to an electrical source for providing electrons to the waveguide core 10 of the QCL to stimulate emission of radiation. FIG. 1c schematically illustrates an optical gain versus energy plot for the narrowband QCL shown in FIG. 1a. Because the QCL shown in FIG. 1a includes only a single type of gain stage, the radiation emitted by the QCL is confined to a narrow spectral range as shown in FIG. 1c.

An exemplary heterogeneous stage QCL was developed by Hugi et al. This QCL was designed to cover the range from 800 to 1450 cm⁻¹ by grouping 72 stages based on five different active regions designed to emit at 869, 961, 1063, 1176, and 1369 cm⁻¹ respectively (corresponding to wavelengths of 11.5, 10.4, 9.4, 8.5, and 7.3 μm). In such broadband QCL designs, all of the stages are typically grown sequentially in a single stack comprising the core of the laser waveguide. Every wavelength within the laser emission spectrum corresponds to an optical mode, which overlaps with the waveguide core. This particular design arrangement is typically chosen to (1) limit the amount of material that needs to be grown, (2) guarantee that the waveguide does not support more than one optical mode along the growth direction for any wavelength in the laser emission spectrum, and (3) have a laser source which corresponds to a single point source. Points (2) and (3) ensure a good beam quality close to the diffraction limit and are important for some applications.

FIG. 1b shows a QCL based on heterogeneous cascades in which gain is provided over a broad spectral range. The broadband QCL in FIG. 1b includes multiple gain stages 30 each having an emission spectra centered at nearby wavelengths. FIG. 1d schematically illustrates an optical gain vs. energy plot for the broadband QCLs shown in FIG. 1b. Because the QCL in FIG. 1b includes multiple types of gain stages, the radiation emitted by the QCL covers a broad spectral range as shown in FIG. 1d. The waveguide design for the narrowband QCL in FIG. 1a and the broadband QCL in FIG. 1b is similar and supports only a single optical mode along the growth (vertical) direction.

### SUMMARY

Applicants have recognized and appreciated that the type of waveguide geometry used in conventional broadband QCLs (e.g., see FIG. 1b) may limit the performance of the laser including the spectral coverage that is achievable. For example, a QCL stage may be designed to provide optical gain over a specific wavelength range at the expense of optical absorption in other parts of the spectrum. In previous conventional broadband QCL devices, the optical mode for a given wavelength typically overlaps with the cascades providing gain at a particular wavelength and also overlaps the cascades that have a significant absorption coefficient. Such a geometry may limit the gain available for lasing or even prevent lasing over broad wavelength ranges.

More generally, Applicants have recognized and appreciated that the previous methods to achieve QCLs with broadband wavelength coverage may be improved by designing such lasers to reduce cross absorption and/or gain competition between multiple groups of cascades in the laser.

Accordingly, some embodiments of the invention are directed to a broadband quantum cascade laser (QCL), comprising a first gain region configured to output a first optical mode, a second gain region configured to output a second optical mode, and at least one spacer layer disposed between the first gain region and the second gain region, the at least one spacer layer having sufficient dimension such that the first optical mode and the second optical mode do not appreciably overlap.

Some embodiments are directed to a broadband quantum cascade laser, comprising a plurality of gain regions and at least one spacer layer interposed between at least two of the plurality of gain regions, the at least one spacer layer configured to reduce a cross absorption and/or gain competition between the plurality of gain regions.

Some embodiments are directed to a method for providing broadband radiation emission from a quantum cascade laser. The method comprises interposing a spacer layer between at least two gain regions in the quantum cascade laser, the spacer layer having sufficient thickness to reduce cross-absorption and/or gain competition between the at least two gain regions.

Some embodiments are also directed to a method for limiting gain saturation for cascades or groups of identical cascades emitting at the same wavelength.

The various embodiments of QCLs disclosed herein may be employed in a number of applications to facilitate reliable detection of trace amounts of chemicals (e.g., drugs, pollutants) with high sensitivity and selectivity. For example, a QCL according to one or more embodiments of the present invention and operating in the mid-infrared region may be used for sensing and analyzing of chemical and biological agents, as many gas- and liquid-phase chemicals have characteristic absorption features in the mid-infrared region. Thus, sensors incorporating QCLs according to the present invention may be used to identify such chemical or biological agents. Some exemplary applications of the QCLs disclosed herein include, but are not limited to, chemical sensing include medical diagnostics, such as breath analysis, pollution monitoring, environmental sensing of the greenhouse gases responsible for global warming, and remote detection of toxic chemicals and explosives.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference or otherwise referenced herein should be accorded a meaning most consistent with the particular concepts disclosed herein.

### BRIEF DESCRIPTION OF THE DRAWINGS

The drawings are not necessarily to scale, emphasis instead generally being placed upon illustrating the principles of the invention.

FIGS. 1a and 1b show, respectively, a schematic of narrowband and a broadband prior art laser;

FIGS. 1c and 1d show optical gain versus wavelength plots for the lasers illustrated in FIGS. 1a and 1b, respectively;

FIG. 2 illustrates a schematic level diagram representing some energy states in a QCL active region design;

FIG. 3 shows a schematic representation of a net gain of a QCL stage biased beyond a transparency point;

FIG. 4a illustrates a cross-section of a QCL with a plurality of gain stages in accordance with some embodiments of the invention;

FIG. 4b schematically shows emission spectra for cascades in the QCL of FIG. 4a;

FIG. 5a illustrates a cross-section of a QCL designed to limit cross absorption in accordance with some embodiments of the invention;

FIGS. 5b and 5c show emission spectra for cascades in a first gain medium and a second gain medium, respectively, for the QCL of FIG. 5a;

FIG. 6a illustrates a cross-section of a QCL designed to limit gain competition in accordance with some embodiments of the invention;

FIGS. 6b and 6c show emission spectra for cascades in a first gain medium and a second gain medium, respectively, for the QCL of FIG. 6a; and

FIG. 7 illustrates an exemplary QCL fabricated in accordance with some embodiments of the invention.

### DETAILED DESCRIPTION

Following below are more detailed descriptions of various concepts related to, and embodiments of, inventive methods and apparatus according to the present disclosure for ultrabroadband quantum cascade lasers. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

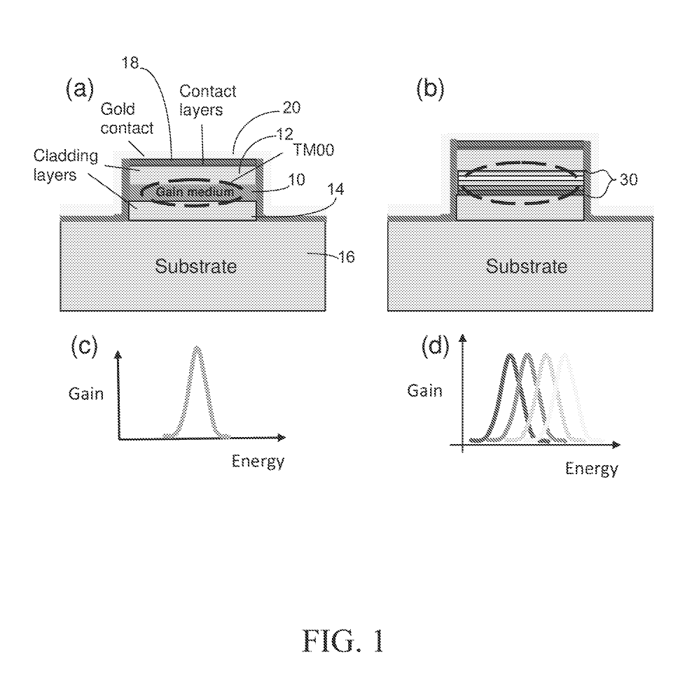

Applicants have recognized that the type of waveguide geometry used in conventional broadband QCLs (e.g., see FIG. 1b) may limit the performance of the laser including the spectral coverage that is achievable. For example, a QCL stage may be designed to provide optical gain over a specific wavelength range at the expense of optical absorption in other parts of the spectrum. In previous broadband QCL devices, the optical mode for a given wavelength typically overlaps with the cascades providing gain at a particular wavelength and also overlaps the cascades that have a significant absorption coefficient. Such a geometry may limit the gain available for lasing or even prevent lasing over broad wavelength ranges.

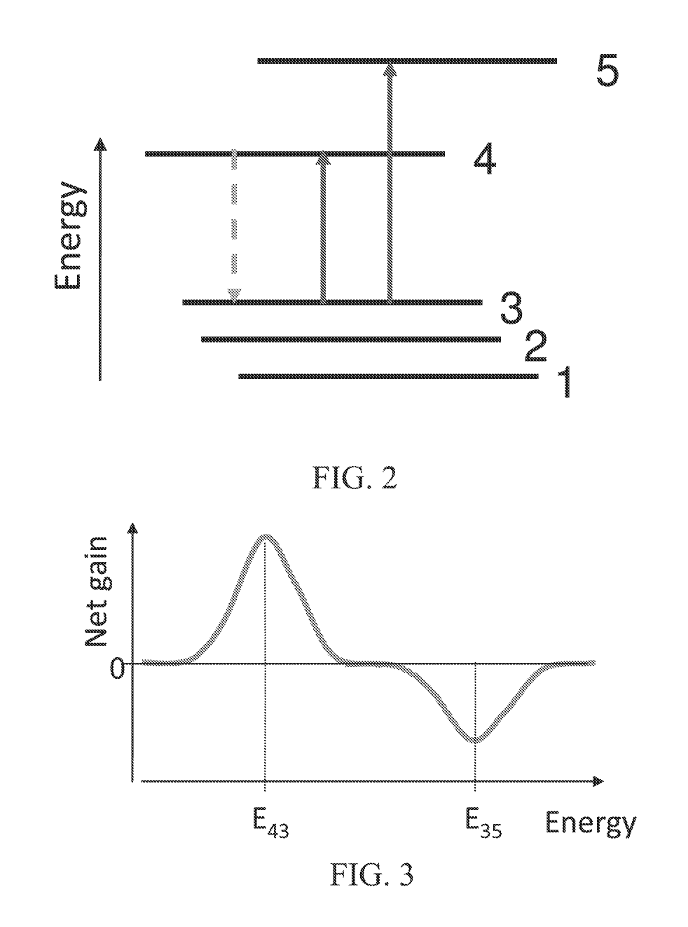

FIG. 2 illustrates a schematic level diagram representing some of the energy states or levels in a standard QCL active region design. It should be appreciated that the energy states shown in FIG. 2 do not necessarily correspond to actual energy states within any particular QCL structure; rather, the generalized energy states shown in FIG. 2 are conceptually representative of important energy states of a QCL for purposes of the present discussion.

Levels 3 and 4 are the upper and the lower laser level respectively. A primary goal of a QCL is to facilitate and maintain a population inversion between the upper and lower laser levels (more electrons in the upper level than the lower level) to facilitate generation of radiation. Once electrons relax from the upper laser level 4 to the lower laser level 3, the electrons further relax through the energy levels below the lower laser level 3 (e.g., levels 1 and 2). That is, levels 1 and 2 help to efficiently deplete the lower laser level to build population inversion. Levels above the upper laser level 4 (e.g., level 5) are typically considered “parasitic levels,” as electrons may inadvertently populate these higher electronic levels rather than the upper laser level 4 (e.g., due to thermal stimulation or radiation scattering) and thereby adversely impact population inversion (e.g., by decreasing an injection efficiency of electrons into the upper laser level). The dashed arrow in FIG. 2 indicates the laser transition that produces gain and the solid arrows indicate important absorption channels in the QCL.

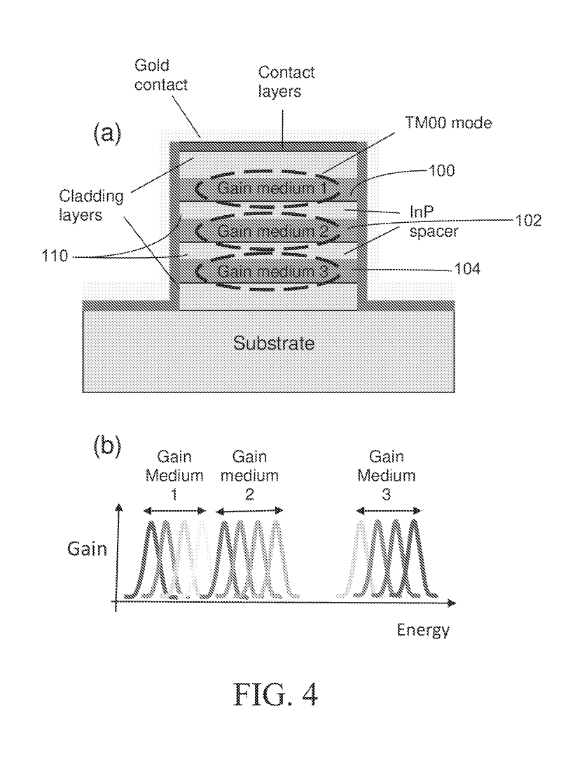

The waveguide losses in QCLs are largely due to absorption processes between the electronic levels confined in the injector and the active regions. These processes include two-photon absorption and absorption at low energy due to the strong dipole moments between the levels labeled 4 and 5 shown in FIG. 2. The absorption processes between the lower laser level 3 and states lying at higher energy is another example. The thermal population of the lower laser level is not negligible at temperatures relevant to most QCL applications as it is at the origin of the so-called transparency current, which accounts for a significant portion of the threshold current density. This can lead to significant absorption between the levels 3 and 5, as illustrated by the negative net gain shown in FIG. 3.

FIG. 3 shows a schematic representation of the net gain of a typical QCL stage biased beyond the transparency point described above. Optical gain is obtained at the energy corresponding to the laser transition E₄₃. Typical values for E₄₃ and E₃₅ are between 90-300 meV. Although absorption features corresponding to the optical transitions between closely spaced states such as levels 1 and 2 or 4 and 5 are also expected below 90 meV, they are not shown in FIG. 3.

Increasing the current beyond the transparency current allows for gain at the energy corresponding to the laser transition, but does not significantly reduce the absorption between the levels 3 and 5 as shown schematically in FIG. 3. The energy difference E₄₅ between the upper laser level 4 and parasitic level 5 typically ranges between 50 to 100 meV (400 to 800 cm⁻¹) and it is often challenging to obtain lasing at the wavelength corresponding to E₄₅ using previous broadband QCL devices due to the reabsorption process described above.

Additionally, Applicants have appreciated that previous broadband QCL designs also suffer from gain competition due to the homogeneously broadened nature of the gain in individual cascades and the fact that the gain curve of cascades designed to emit at a specific wavelength generally overlaps with the gain curve of cascades designed to emit at other wavelengths as shown in FIG. 1d. Because of the homogeneously broadened nature of the gain in individual cascades, lasing efficiently depletes population inversion via stimulated emission in all the cascades providing gain at the wavelengths where lasing occurs. Lasing at a specific wavelength leads therefore to a reduction of population inversion in cascades designed to lase at other wavelengths and which contribute little to the gain at the wavelengths where lasing occurs. This leads to a decrease of the gain in the spectral regions where gain is available but is too small to compensate optical losses, which makes it challenging to obtain, for example, broadband emission without gaps.

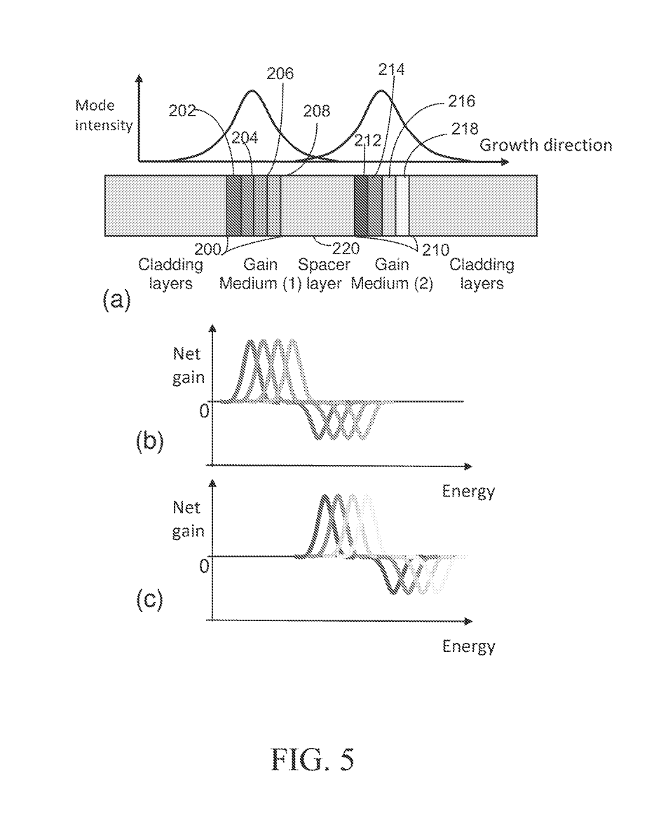

Embodiments of the present invention are designed to alleviate some or all of the aforementioned limitations of conventional broadband QCLs. FIG. 4 illustrates a cross-section of a ridge QCL designed in accordance with some embodiments of the invention to provide gain over an ultrabroad spectral range. The exemplary laser shown in FIG. 4a includes three separate gain regions 100, 102, and 104 spatially separated by one or more spacer layers 110. Each gain region comprises a plurality of gain stages or “cascades,” each having an emission spectrum centered at a different wavelength as shown schematically in FIG. 4b. Three optical modes, each overlapping with a different gain region are supported along the growth (vertical) direction as indicated by the dashed lines in FIG. 4a.

For a given wavelength, the QCL design shown in FIG. 4a reduces the mode overlap with absorbing cascades while also increasing the mode overlap with the cascades providing gain. In some embodiments, the spacer layers 110 comprise bulk InP or InGaAs layers or a combination of bulk InP and InGaAs layers, although other semiconductor materials may alternatively be used. In some embodiments, the spacer layers 110 are thick enough to force the modes to overlap with only one group of cascades as shown schematically in FIG. 4a. As illustrated in FIG. 4b, the groups of cascades 100 and 102 may enable broad spectral coverage in the so-called LWIR band (i.e., in the wavelength range between 8 and 12 μm) while the group of cascades 104 may enable spectral coverage in the so-called MWIR band (i.e., in the wavelength range between 3 and 5 μm). When considered together, the contributions of the groups of cascades 100, 102, and 104 results in broadband spectral output from the exemplary QCL shown in FIG. 4.

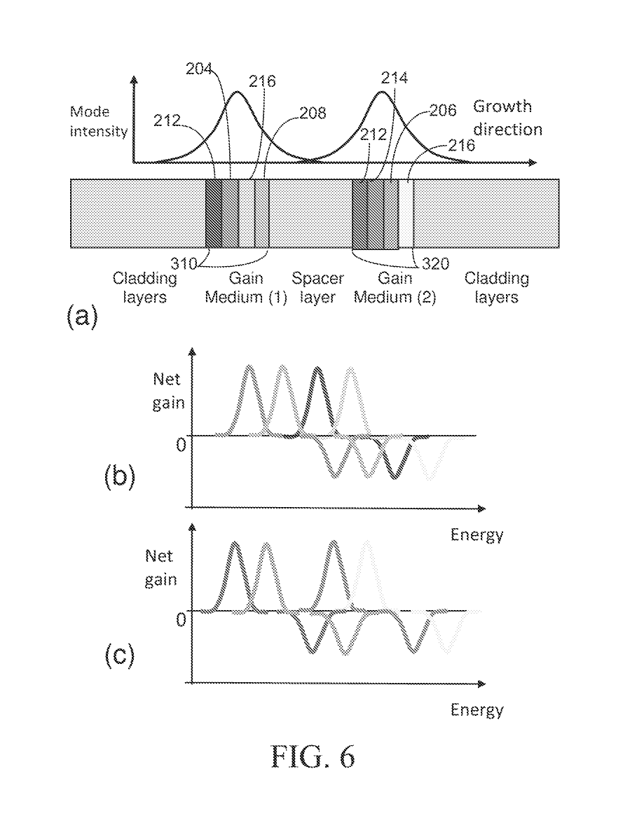

As described above, in some instances optical cross absorption between groups of cascades may limit the ability of conventional broadband QCL devices to provide gain over very broad spectral ranges or to provide continuous wavelength coverage over at least one spectral range. FIG. 5 illustrates an exemplary ridge QCL according to one embodiment of the present invention designed to overcome this problem, namely to reduce optical cross absorption so as to provide gain over an ultrabroad spectral range. Although the particular structure illustrated in FIG. 5a includes only two groups of cascades (gain regions 200 and 210), it should be appreciated that any number of cascade groups may be used and embodiments of the invention are not limited in this respect. Each of the two groups of cascades 200 and 210 is designed to emit radiation at different wavelengths. A first group of cascades 200 comprises gain stages 202, 204, 206, and 206 which provide gain at low energies. The first group of cascades 200 is spatially separated by a spacer layer 220 from a second group of cascades 210 comprising gain stages 212, 214, 216, and 218 which provide gain at higher energies. In particular, the energy range at which the second group of cascades 210 provides gain overlaps with the energy range at which the first group of cascades 200 produces absorption effects as shown in FIGS. 5b and 5c.

The configuration shown in FIG. 5 may be thought of as two coupled waveguides. The thickness of the spacer layer 220 in particular may be used to control the overlap of the optical modes and to design an optical mode with an increased overlap with the cascades with high gain and a reduced overlap with the cascades with high absorption cross section. Other parameters including the number of cascades in the QCL gain regions or the addition of InGaAs bulk layers or plasmon layers may also be designed to reduce cross absorption between the groups of cascades. If the thickness of the spacer layers is large enough (e.g., a few microns thick), the groups of cascades act as two independent waveguides resulting in two optical modes with little to no overlap with each other (see FIG. 5(c)), thereby reducing the effects of cross absorption. Thus, two optical modes with little overlap may be supported, which allows the mode overlap with absorbing cascades to be reduced, while increasing the mode overlap with the cascades providing gain.

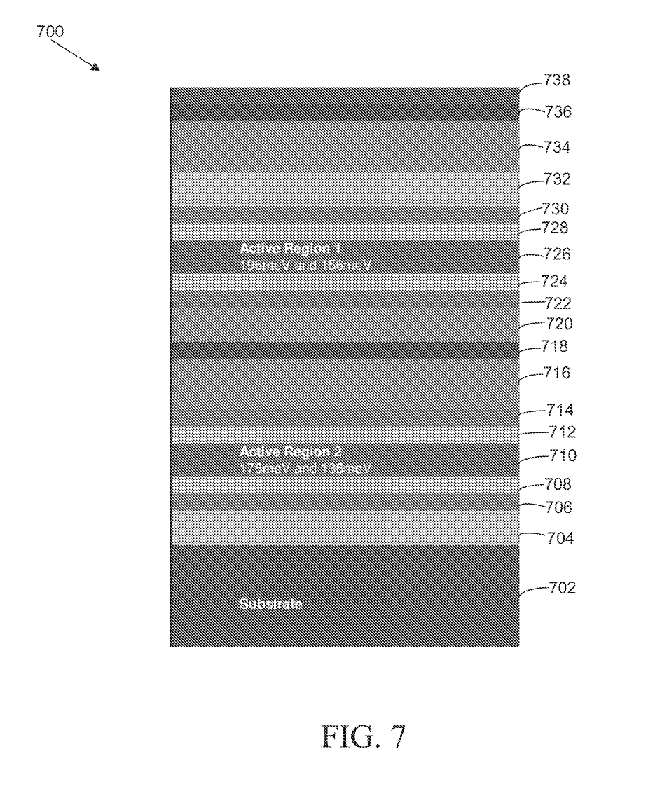

Applicants have also recognized and appreciated that the detrimental effects of the homogeneous broadening in QCLs, as described above, may be reduced by placing gain stages with overlapping gain curves in different groups of cascades as shown in FIG. 6. FIG. 6 illustrates an exemplary ridge QCL designed to address problems related to the homogeneous nature of the gain observed in QCL cascades. Similar to the waveguide in FIG. 5, only two groups of cascades 310 and 320 are shown, although it should be readily appreciated that more groups of cascades may also be used and embodiments of the invention are not limited in this respect. The two groups of cascades 310 and 320 may be designed to support optical modes with little overlap. A cross section along the growth direction of the relevant elements of the waveguide is shown in FIG. 6a. The exemplary QCL shown in FIG. 6 is designed to reduce competition between gain stages within a cascade group by distributing the gain stages in the different cascade groups as shown in FIGS. 6b and 6c. That is, the first group of cascades 310 comprises gain stages 204 and 208 which provide gain at low energies and gain stages 212 and 216 which provide gain at high energies, whereas the second group of cascades 320 comprises gain stages 202 and 206 which provide gain at low energies and gain stages 214 and 218 which provide gain at high energies. By dividing overlapping gain stages into multiple cascade groups, gain competition between cascades with overlapping gain curves within a cascade group is reduced without sacrificing the desired ultrabroadband spectral coverage of the QCL, as described above in connection with FIG. 5.

Some embodiments are directed to mitigating the detrimental effects of gain saturation, which takes place in heterogeneous QCLs and is mostly pronounced in QCLs having only identical gain stages emitting at the same wavelength. Gain saturation is a general phenomenon that takes place in optical amplifiers and lasers and is related to the fact that the amplification of light in such devices can not be infinite. The amplification and hence the optical gain decreases as the laser intracavity power increases, thereby limiting the maximum power achievable. In QCLs, spatially separating identical cascades emitting at the same wavelength as described above limits the power density that each of the cascades experiences and therefore limits gain saturation, leading to higher power. Gain saturation is also sometimes referred to as gain compression.

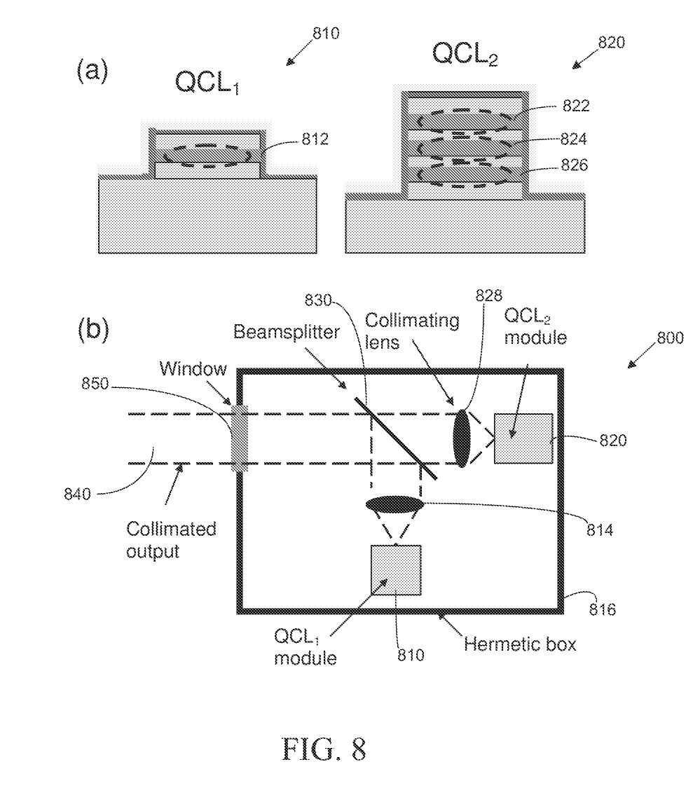

FIG. 7 illustrates an exemplary QCL 700 fabricated in accordance with some embodiments of the invention. Exemplary QCL 700 comprises a plurality of layers grown on substrate 702. Substrate 702 may comprise multiple layers of InP having a doping concentration of 0.5-1e17 cm⁻³. A first cladding layer 704 comprising InP having a doping concentration of 5e16 cm⁻³ and a thickness of 1.5 μm may be grown on substrate 702. To provide a smooth transition from InP to InGaAs, a Si grade InGaAsP layer 706 having a doping concentration of 3e16 cm⁻³ and a thickness of 300 Å may be grown on cladding layer 704. Layer 708 comprising InGaAs having a doping concentration of 3e16 cm⁻³ and a thickness of 3000 Å may be provided on layer 706. Gain region 710 comprises two types of cascades emitting at wavelengths of 7.05 and 9.12 μm, respectively, and the total thickness of gain region 710 may be 2.3 μm. Layer 712 comprising InGaAs having a doping concentration of 3e16 cm⁻³ and a thickness of 2000 Å may be provided on gain region 710, and Si grade InGaAsP layer 714 having a doping concentration of 3e16 cm⁻³ and a thickness of 300 Å may be grown on layer 712 to provide a smooth transition between layer 712 and cladding layer 716 comprising InP having a doping concentration of 3e16 cm⁻³ and a thickness of 3 μm. Plasmon layer 718 having a thickness of 5000 Å and comprising highly-doped (e.g., 1e19 cm⁻³) InP may be grown on cladding layer 716 to reduce the refractive index and help prevent the optical mode from penetrating this layer.

Cladding layer 720 comprising InP having a doping concentration of 3e16 and a thickness of 2.5 μm may be grown on plasmon layer 718. To provide a smooth transition from InP to InGaAs, an Si grade InGaAsP layer 722 having a doping concentration of 3e16 cm⁻³ and a thickness of 300 Å may be grown on cladding layer 720. Layer 724 comprising InGaAs having a doping concentration of 3e16 cm⁻³ and a thickness of 2000 Å may be provided on layer 722. Gain region 726 may be grown on layer 724 and may comprise two types of cascades emitting at wavelengths of 6.33 and 7.95 μm, respectively. The total thickness of gain region 726 may be 2.3 μm. Layer 728 comprising InGaAs having a doping concentration of 3e16 cm⁻³ and a thickness of 3000 Å may be provided on gain region 726, and Si grade InGaAsP layer 730 having a doping concentration of 3e16 cm⁻³ and a thickness of 300 Å may be grown on layer 728 to provide a smooth transition between layer 728 and cladding layer 732 comprising InP having a doping concentration of 5e16 cm⁻³ and a thickness of 1.5 μm. Cladding layer 734 comprising Applicants also have recognized and appreciated that the present invention can also mitigate the detrimental effects of gain saturation, which takes place in heterogeneous QCLs and is mostly pronounced in QCLs having only identical gain stages emitting at the same wavelength. Gain saturation is a general phenomenon taking place in optical amplifiers and lasers and is related to the fact that the amplification of light in such devices can not be infinite. The amplification and hence the optical gain must decrease as the laser intracavity power increases, limiting therefore the maximum power achievable. In QCLs, separating spatially, as described above, identical cascades emitting at the same wavelength limits the power density that each of the cascades experience and therefore limits gain saturation, leading to higher power. Gain saturation is also commonly known as gain compression.

InP having a doping concentration of 1e17 and a thickness of 2 μm may be grown on cladding layer 732. Plasmon layer 736 having a thickness of 5000 Å and comprising highly-doped (e.g., 1e19 cm⁻³) InP may be grown on cladding layer 734 to reduce the refractive index and help prevent the optical mode supported by gain region 726 from penetrating this layer. To provide a good electrical contact, contact layer(s) 738 comprising highly doped InGaAs (e.g., doping concentration of 1e19) and a thickness of 200 Å may be grown on plasmon layer 736. The total thickness of exemplary QCL 700 is 17.22 μm.

It should be appreciated that QCL 700 is described merely for purposes of illustration and layers comprising different materials, doping concentrations, and/or dimensions may alternatively be used. In accordance with some embodiments, the doping concentration in each layer may be selected to minimize optical losses. Although QCL 700 comprises only two gain regions 710 and 726, QCLs having additional gain regions may also be used and embodiments of the invention are not limited in this respect.

The introduction of one or more spacer layers in a broadband QCL design may also improve laser performance by improving the heat dissipation capability of the laser structure. Thermal management in QCLs is in general challenging because of the poor thermal conductivity of the QCL cascades and the poor electrical to optical conversion efficiency of QCLs. Heat dissipation issues are especially important in broadband QCLs because of the large number of cascades required to cover the desired wavelength range, which results in a thick region of poorly conductive material where the heat becomes trapped. The introduction of spacer layers may provide a path to transport and distribute the heat produced in the direction perpendicular to the growth direction. Introduction of one or more cladding layers bilaterally oriented with respect to waveguide core of the QCL may additionally facilitate heat transfer from the waveguide core. The improved heat dissipation may help reduce the temperature gradient across the waveguide core.

Applicants have also recognized that the introduction of one or more spacer layers in a broadband QCL may, in some instances, decrease the beam quality of the laser. For example, depending on the thickness of the spacer layer(s), the output of the QCL may approximate multiple point sources rather than a single uniform source. However, this arrangement should be acceptable for a number of applications, including those that do not require the propagation of the laser beam over distances longer than a few meters. External-cavity QCLs integrating ultrabroadband devices according to some embodiments of the invention are also contemplated.

Rather than forming a QCL with multiple waveguides grown on the same substrate as described above in connection with FIG. 6, some embodiments are directed to a QCL subsystem that includes multiple waveguides formed on separate substrates. One or both of the waveguides formed on the separate substrates may include one or more gain regions separated by one or more spacer layers, and aspects of the invention are not limited with respect to any particular combination of gain regions and spacer layers. In one implementation of such a QCL subsystem, only compatible cascades may be grown together on a substrate and the output of the waveguides may be combined using external optics. FIG. 8b illustrates such a QCL subsystem 800 that includes a first QCL 810 and a second QCL 820 mounted in a hermetic box or other suitable type of container. As shown in FIG. 8a, QCL 810 may include a single gain region 812 and QCL 820 may include multiple gain regions 822, 824, and 826 separated by spacer layers. It should be appreciated that QCL 810 and QCL 820 may include any number of gain regions and the number of gain regions illustrated in FIG. 8a is shown merely for exemplary purposes. At least one of the QCLs in QCL subsystem 800 may be a broadband QCL as described above in accordance with some embodiments of the invention.

The beams output from QCL 810 and QCL 820 may be combined using external optics as shown in FIG. 8b. For example, in one embodiment, the output of QCL 810 may be associated with collimator 814 and the output of QCL 820 may be associated with collimator 828. The collimated beams from QCL 810 and QCL 820 may be combined using beamsplitter 830 or other suitable optics to produce collimated output beam 840 that may projected out of QCL subsystem 800 through window 850. With each of QCLs 810 and 820 contributing energy in different portions of the spectrum, the resultant output beam 840 may constitute a broadband QCL source with a broad spectral coverage.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of and “consisting essentially of shall be closed or semi-closed transitional phrases, respectively, as set forth in the United States Patent Office Manual of Patent Examining Procedures, Section 2111.03.

1. A quantum cascade laser (QCL), comprising:
a first gain region configured to output a first optical mode;
a second gain region configured to output a second optical mode; and
at least one spacer layer disposed between the first gain region and the second gain region, the at least one spacer layer having sufficient dimension such that the first optical mode and the second optical mode do not appreciably overlap.

2. The QCL of claim 1, wherein the at least one spacer layer comprises InP.

3. (canceled)

4. The QCL of claim 1, comprising at least two groups of identical gain stages spatially separated in order to reduce an intracavity power density experienced by at least one of the identical gain stages resulting in a reduction of gain saturation.

5. The QCL of claim 1, wherein the first gain region comprises a first plurality of heterogeneous gain stages, each of the first plurality of heterogeneous gain stages configured to provide gain in a first energy range, and wherein the second gain region comprises a second plurality of heterogeneous gain stages, each of the second plurality of heterogeneous gain stages configured to provide gain in a second energy range.

6. The QCL of claim 5, wherein the first plurality of heterogeneous gain stages in the first gain region exhibit absorptive effects in the second energy range.

7. The QCL of claim 1, wherein the first gain region comprises a first plurality of heterogeneous gain stages and the second gain region comprises a second plurality of heterogeneous gain stages, wherein each of the first plurality of heterogeneous gain stages and/or each of the second plurality of heterogeneous gain stages are selected to reduce competition between gain stages within the first gain region and/or the second gain region, respectively.

8. The QCL of claim 1, wherein the first gain region and the second gain region are formed within a waveguide core of the QCL, the QCL further comprising:
a first cladding layer and a second cladding layer, the waveguide core being arranged between the first cladding layer and the second cladding layer.

9. The QCL of claim 8, further comprising a first electrical contact electrically connected to the first cladding layer and a second electrical contact electrically connected to the second cladding layer.

10. (canceled)

11. (canceled)

12. The QCL of claim 1, wherein at the first gain region is configured to reduce gain competition between gain stages in the first gain region.

13. The QCL of claim 1, wherein the first gain regions comprises first gain stages configured to emit radiation in a first energy range interspersed with second gain stages configured to emit radiation in a second energy range, wherein the first energy range and the second energy range are non-overlapping.

14. (canceled)

15. (canceled)

16. The QCL of claim 1, further comprising:
at least one bilateral cladding layer thermally coupled to the at least one spacer layer and configured to facilitate removal of thermal energy from the waveguide core.

17. (canceled)

18. A method for providing broadband radiation emission from a quantum cascade laser, the method comprising:
interposing a spacer layer between at least two gain regions in a waveguide core of the quantum cascade laser, the spacer layer having sufficient thickness to reduce cross-absorption between the at least two gain regions.

19. The method of claim 18, further comprising:
selecting the thickness of the spacer layer to provide a uniform output from the quantum cascade laser.

20. The method of claim 18, further comprising:
configuring a first gain region of the at least two gain regions to provide gain in a first energy region and absorption in a second energy region; and
configuring a second gain region of the at least two gain regions to provide gain in the second energy region and absorption in a third energy region.

21. The method of claim 18, wherein the plurality of gain regions comprises a first gain region including first gain stages configured to emit radiation in a first energy range and a second gain region comprising second gain stages configured to emit radiation in a second energy range, the method further comprising:
reducing gain competition between the first gain stages in the first gain region and/or the second gain stages.

22. The method of claim 21, wherein reducing gain competition comprises reconfiguring each of the first gain region and the second gain region to include some of the first gain stages and some of the second gain stages.

23. A broadband quantum cascade laser (QCL) system, comprising:
a first QCL grown on a first substrate, the first QCL comprising a first gain region configured to output a first optical mode; and
a second QCL grown on a second substrate, the second QCL comprising a second gain region configured to output a second optical mode.

24. The system of claim 23, wherein the first QCL further comprises:
a second gain region configured to output a third optical mode; and
at least one spacer layer disposed between the first gain region and the second gain region, the at least one spacer layer having sufficient dimension such that the first optical mode and the third optical mode do not appreciably overlap.

25. The system of claim 17, further comprising:
at least one optic configured to combine an output of the first QCL and an output of the second QCL to form a broadband QCL source.

26. The system of claim 25, wherein the at least one optic comprises:
a beamsplitter oriented to combine an output of the first QCL and an output of the second QCL.

27. (canceled)
